(19) United States
(12) Patent Application Publication
(10) Pub. No.: US 2004/0182602 A1
(43) Pub. Date: Sep. 23, 2004

(54) High frequency electronic circuit component

(76) Inventors: Toshiya Satoh, Kanasago (JP); Masahiko Ogino, Hitachi (JP); Sigehisa Motowaki, Hitachi (JP); Yuzuru Shimazaki, Sendai (JP); Yoko Furukawa, Hitachi (JP)

Correspondence Address: DICKSTEIN SHAPIRO MORIN & OSHINSKY LLP, 2101 L STREET NW, WASHINGTON, DC, 20037-1526, US

(21) Appl. No.: 10/795,521

(22) Filed: Mar. 9, 2004

(30) Foreign Application Priority Data
Mar. 17, 2003 (JP) 2003-071203

(51) Int. Cl. H05K 1/03

(52) U.S. Cl. 174/258

(57) ABSTRACT

The present invention aims at miniaturizing a balance-unbalance converter using the conventional connection lines and reducing the cost thereof. The present invention provides a high frequency electronic circuit component constituted by three transmission lines formed on at least the same surface, wherein the first and second transmission lines face each other on the same surface and are connected to each other electromagnetically, and the first and third transmission lines face each other on the same surface and are connected to each other electromagnetically. Alternatively, the present invention provides a high frequency electronic circuit component constituted by at least four transmission lines, wherein the first and second transmission lines face each other on the same surface and are connected to each other electromagnetically, the third and fourth transmission lines face each other on the same surface and are connected to each other electromagnetically, and the first and third transmission lines are in electric communication with each other. A miniaturized high frequency electronic circuit component of high performances such as a balun can be provided at a low cost by the present invention.

### FIELD OF THE INVENTION

The present invention relates to a high frequency electronic component and the production technique thereof, particularly to a high frequency electronic component using connection lines which is used as a balun (balance-unbalance signal converter) and the technique applied effectively to the production thereof.

### BACKGROUND OF THE INVENTION

As a high frequency component using connection lines, there is, for example, a balun (balance-unbalance converter). The balun is to convert, for example, the balance signal of a balance transmission line and the unbalance signal of an unbalance transmission line into each other. In this connection, the balance transmission line has a pair of two signal lines, and the balance signal is transmitted as the potential difference between the two signal lines. On the other hand, in the unbalance transmission line the unbalance signal is transmitted as the potential of one signal line to the ground potential (zero potential). For example, a coaxial line or a microstrip line in the form of a substrate corresponds to the unbalance transmission line.

U.S. Pat. No. 6,097,273 discloses a technique relating to a balun having two pairs of spirals which face each other on two different layers.

JP-A-2001-144513 discloses a technique constituting a high frequency component which can be obtained by use of a ceramic dielectric sheet and wiring formation by the printing method or the like.

### SUMMARY OF THE INVENTION

In a balun having two pairs of spirals which face each other on two different layers, the number of layers constituted is many, which invites increase in production cost. Furthermore, two pairs of spirals are arranged in parallel, which invites increase in size of the balun.

Furthermore, in the so-called thick film lamination step using a ceramic dielectric sheet, the wire width of metal wiring constituting transmission lines is about 50 μm, and in order to attain the desired characteristics it is necessary to increase the component size or to laminate into plural layers, which invites increase in cost.

The present invention has been attained in view of such technical background, and aims at providing a high frequency electronic circuit component wherein high frequency electronic components such as a balun are integrated at high performances and at a high density.

In order to attain said object, a high frequency electronic circuit component wherein electronic components such as a balun are integrated-at a high density, can be obtained in accordance with (1) a high frequency electronic circuit component constituted by three transmission lines formed on at least the same surface, wherein the first and second transmission lines face each other on the same surface and are connected to each other electromagnetically, and the first and third transmission lines face each other on the same surface and are connected to each other electromagnetically.

Furthermore, in order to attain said object, a high frequency electronic circuit component wherein electronic components such as a balun are integrated at a high density, can be obtained in accordance with (2) a high frequency electronic circuit component constituted by at least four transmission lines, wherein the first and second transmission lines face each other on the same surface and are connected to each other electromagnetically, the third and fourth transmission lines face each other on the same surface and are connected to each other electromagnetically, and the first and third transmission lines are in electric communication with each other.

Moreover, in order to attain said object, in addition to the effect of (1) or (2), electronic components such as a balun can be integrated to exhibit higher performances in accordance with (3) the high frequency electronic circuit component of (1) or (2), wherein peripheries of the transmission lines are covered with an organic insulation material, and said transmission lines and said organic insulation material are formed on an insulating substrate.

Furthermore, in order to attain said object, in addition to the effect of (3), a high frequency electronic circuit component of high performances can be obtained at a lower cost owing to the low cost, high smoothness, high insulation performance and low dielectric loss tangent of a glass substrate in accordance with (4) the high frequency electronic circuit component of (3), wherein the insulating substrate is a glass substrate.

Moreover, in order to attain said object, in addition to the effect of (3), a high frequency electronic circuit component can be obtained at a lower cost because production process can be shortened and production cost can be reduced in accordance with (5) the high frequency electronic circuit component of (3), wherein the organic insulation material is a light-sensitive organic insulation material.

Furthermore, in order to attain said object, in addition to the effect of (3), a high frequency electronic circuit component of higher performances and higher efficiency can be obtained at a low cost owing to the low cost, low dielectric constant and low dielectric loss tangent of a low dielectric loss tangent resin composition in accordance with (6) the high frequency electronic circuit component of (3), wherein the organic insulation material is a low dielectric loss tangent resin composition containing a cross-linking component having plural styrene groups represented by the following general formula (1) and furthermore containing a high polymer having a weight average molecular weight of 5000 or higher:

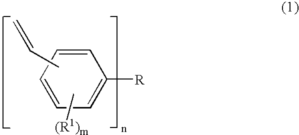

, wherein R means a hydrocarbon skeleton which may have a substituent, R¹ means either one of hydrogen, methyl or ethyl, m means an integer of 1-4, and n means an integer of 2 or more.

Moreover, in order to attain said object, in addition to the effect of (3), a high frequency electronic circuit component of high reliability can be obtained owing to the high heat stability of a polyimide in accordance with (7) the high frequency electronic circuit component of (3), wherein the organic insulation material comprises a polyimide resin.

Furthermore, in order to attain said object, in addition to the effect of (3), a high frequency electronic circuit component of higher performances and higher efficiency can be obtained owing to the low dielectric constant and low dielectric loss tangent of a BCB (benzocyclobutene) resin in accordance with (8) the high frequency electronic circuit component of (3), wherein the organic insulation material comprises BCB (benzocyclobutene) resin.

Other objects, features and advantages of the invention will become apparent from the following description of the embodiments of the invention taken in conjunction with the accompanying drawings.

### BRIEF DESCRIPTION OF THE DRAWINGS

FIG. 1 is a plan view showing the first example of the present invention.

FIG. 2 is a schematic sectional view showing the first example of the present invention.

FIG. 3 is a plan view showing transmission lines which constitute the first layer in the first example of the present invention.

FIG. 4 is a plan view showing continuity veers formed in an organic insulation layer which constitutes the second layer in the first example of the present invention.

FIG. 5 is a plan view showing wiring and external terminals which constitute the third layer in the first example of the present invention.

FIG. 6 is a plan view showing the second example of the present invention.

FIG. 7 is a sectional view showing the second example of the present invenion.

FIG. 8 is a plan view showing a wiring portion which constitutes the first layer in the second example of the present invention.

FIG. 9 is a plan view showing continuity veers formed in an organic insulation layer which constitutes the second layer in the second example of the present invention.

FIG. 10 is a plan view showing transmission lines which constitute the third layer in the second example of the present invention.

FIG. 11 is a plan view showing continuity veers formed in an organic insulation layer which constitutes the fourth layer in the second example of the present invention.

FIG. 12 is a plan view showing transmission lines which constitute the fifth layer in the second example of the present invention.

FIG. 13 is a plan view showing continuity veers formed in an organic insulation layer which constitutes the sixth layer in the second example of the present invention.

FIG. 14 is a plan view showing wiring and external terminals which constitute the seventh layer in the second example of the present invention.

The numerals in the drawings have the following meanings:

1: first-transmission line, 2: second transmission line,

3: third transmission line, 4: glass substrate,

5, 6: organic insulation materials,

7: signal input terminal, 8, 9: output terminals,

10, 11: terminals, 12, 17: continuity veers,

18, 20, 22, 24, 26 and 28: wiring, and

19, 21, 23, 25 and 27: external terminals.

### DETAILED DESCRIPTION OF THE INVENTION

The transmission line in the present invention is not particularly limited so long as it is the so-called inductive circuit element, and for example, a spiral type formed on a flat surface or the like is used.

Furthermore, the material of the transmission line is appropriately selected depending on electric conductivity, adhesiveness with peripheral material, forming method and the like. Moreover, the forming method is not particularly limited. For example, Cu may be formed by use of sputtering method or the like, and in consideration of peripheral material Ti, Cr or the like may be formed at the interface between them. Furthermore, a fundamental film may be formed with Cu or the like by sputtering method or the like, and then an additional film may be formed by electrolytic plating method or the like. Moreover, as a patterning method for wiring and inductor elements there can be used a general wiring patterning method such as etching method, liftoff method or the like. Furthermore, printing method or the like may be used with a resin paste containing a metal such as Ag or the like. Moreover, when the forming temperature of said inorganic dielectrics is high, there can be used a metal of high oxidation resistance and high heat resistance such as Pt or the like.

The organic insulation material in the present invention is not particularly limited so long as it is an organic material which is used generally for semiconductor use, and it may be thermosetting or thermoplastic. There can be used, for example, polyimide, polycarbonate, polyester, polytetrafluoro-ethylene, polyethylene, polypropylene, polyvinylidene fluoride, cellulose acetate, polysulfone, polyacrylonitrile, polyamide, polyamide-imide, epoxy resin, maleimide resin, phenol resin, cyanate resin, polyolefin, polyurethane, and a combination thereof. There may be used a mixture of any one of these materials with a rubber component such as acrylic rubber, silicone rubber, or nitrile-butadiene rubber, an organic compound filler such as polyimide filler, or an inorganic filler such as silica. Furthermore, the organic insulation material may be formed by a light-sensitive material containing any one of the above materials.

Particularly polyimide resin is preferable since it is excellent in heat resistance and chemical resistance and furthermore excellent in processability when it is provided with light sensitivity. Furthermore, benzocyclobutene resin has low dielectric loss tangent and is preferable when the condenser of the present invention is used as a high frequency component. Similarly, a low dielectric loss tangent resin composition containing a cross-linking component having plural styrene groups represented by the undermentioned general formula (1) and furthermore containing a high polymer having a weight average molecular weight of 5000 or higher is preferable since transmission loss is reduced. As a skeleton bonding styrene groups in this resin composition, a hydrocarbon skeleton containing an alkylene group such as methylene, ethylene or the like is preferable. Concretely there are cited 1,2-bis(p-biphenyl)ethane, 1,2-bis(m-biphenyl)ethane, and the analogs, and oligomers such as divinylbenzene's homopolymers or copolymers with styrene or the like which have vinyl goups as side chains, and the like.

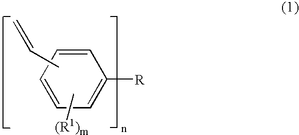

In the above formula (1), R means a hydrocarbon skeleton which may have a substituent, R¹ means either one of hydrogen, methyl or-ethyl, m means an integer of from 1 to 4, and n means an integer of 2 or more.

Furthermore, it is possible to allow the above organic insulation material to have function as a stress cushioning medium. Concretely there are cited fluorine rubber, silicone rubber, fluorinated silicone rubber, acrylic rubber, hydrogenated nitrile rubber, ethylene-propylene rubber, chlorosulfonated polystyrene, epichlorohydrin rubber, butyl rubber, urethane rubber, polycarbonate/acrylonitrile-butadiene-styrene alloy, polysiloxane-dimethylene terephthalate/polyethylene terephthalate-copolymerized polybutylene terephthalate/polycarbonate alloy, polytetrafluoroethylene, fluorinated ethylene-propylene rubber, polyarylate, polyamide/acrylonitrile-butadiene-styrene alloy, modified epoxy resin, modified polyolefin, siloxane-modified polyamide-imide and the like. Moreover, as the forming method thereof, there are a pattern printing method such as printing method, ink-jet method or electrophotographic method, a method which comprises forming an organic insulation material by film-affixing method, spin coat method or the like and then forming a pattern by photographic step, laser or the like, and a combination method thereof.

In addition to the above materials, there may be used various thermosetting resins such as epoxy resin, unsaturated polyester resin, epoxy-isocyanate resin, maleimide resin, maleimide-epoxy resin, cyanic ester resin, cyanic ester-epoxy resin, cyanic ester-maleimide resin, phenol resin, diallyl phthalate resin, urethane resin, cyanamide resin, maleimide-cyanamide resin and the like; and a combination material of two or more kinds of the above resins; and furthermore a material having an inorganic filler or the like incorporated in any one or a combination of the above resins. Moreover, it is possible to control the form of a stress cushioning layer by giving light sensitivity to the above resins and conducting the required exposure-development process.

The insulating substrate in the present invention is not particularly limited, so long as it is a material of high insulation performance so as not to reduce efficiency of each element. Furthermore, the glass substrate in the present invention is not particularly limited, so long as it is a glass substrate of high insulation performance so as not to reduce efficiency of each element, and it is selected in view of strength, processability and the like. Desirably it contains particularly at least one rare earth element selected from the group consisting of Sc, Y, La, Pr, Nd, Pm, Sm, Eu, Gd, Tb, Dy, Ho, Er, Tm, Yb, and Lu. Moreover, desirably a rare earth element is contained in an amount of 0.5-20% by weight calculated in terms of the oxide, Ln₂O₃ wherein Ln is a rare earth element, based on the entire glass, as other components 40-80% by weight of SiO₂, 0-20% by weight of B₂O₃, 0-20% by weight of R₂O wherein R is an alkali metal, 0-20% by weight of RO wherein R is an alkaline earth metal, and 0-17% by weight of Al₂O₃ are contained, and R₂O+RO is 10-30% by weight. Such content ranges improve strength of a glass substrate greatly and furthermore improve the processability thereof conspicuously.

In the electronic circuit component of the present invention, in order to obtain electric connection with exterior an external electrode needs not be formed particularly on a metal terminal but can be formed if necessary. The external electrode is an electric conductor to be electrically connected with the substrate on which the electronic circuit component of the present invention is mounted, and a semiconductor element, and concretely, for example, solder alloy containing tin, zinc and lead, silver, copper, or gold or a ball-like article prepared by coating them with gold and shaping is used for the external electrode. In addition to the above metals, there may be used one of molybdenum, nickel, copper, platinum, titanium and the like, or a combination alloy of two or more of them, or a terminal of multiple film structure of two or more of them. Furthermore, as the forming method thereof, there can be used all of the conventional known methods such as a method of transcribing a ball-like electrode by use of a mask or the like, a method of printing a pattern, and the like.

### DESCRIPTION OF PREFERRED EMBODIMENTS

Hereinafer, the present invention will be concretely described by way of working examples. In addition, in all the drawings for describing the present invention the same symbols are given to elements having the same functions, and the repeated descriptions thereof will be omitted.

### EXAMPLE 1

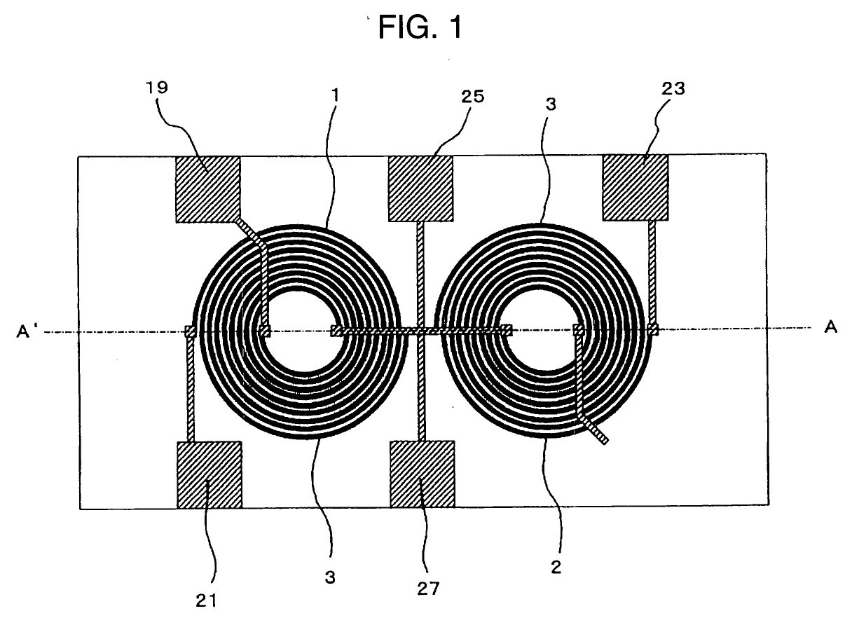

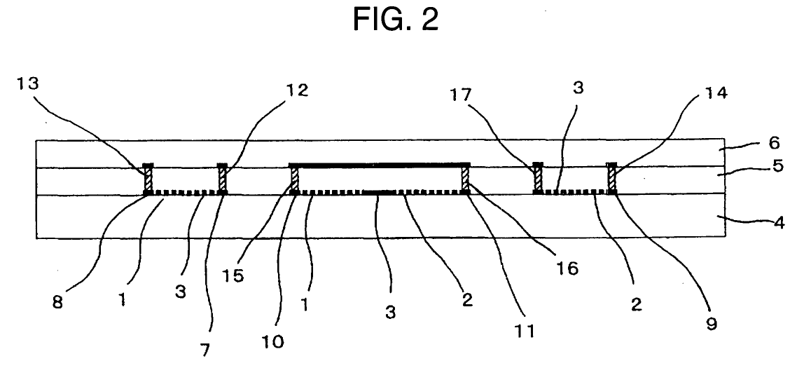

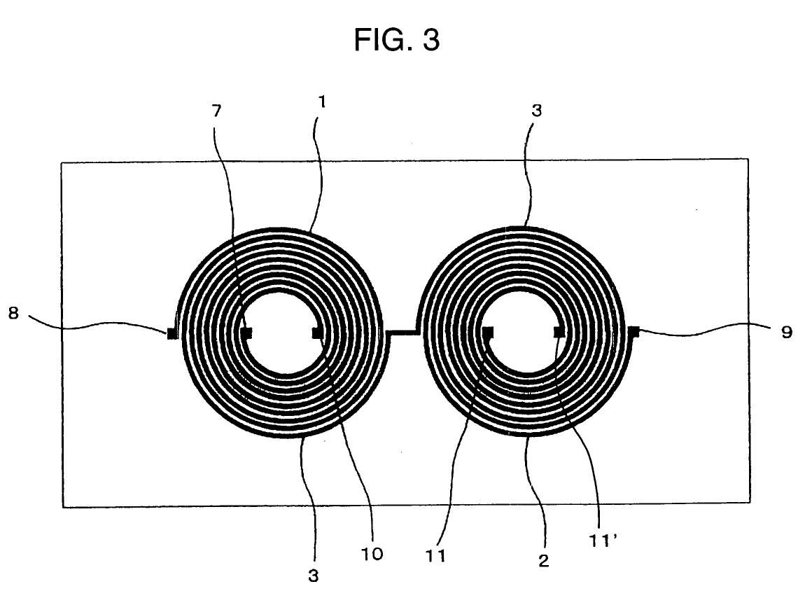

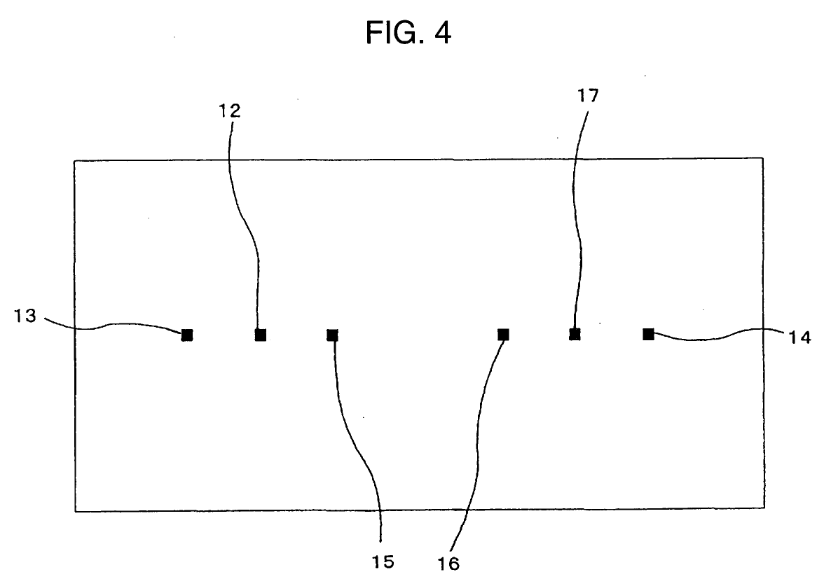

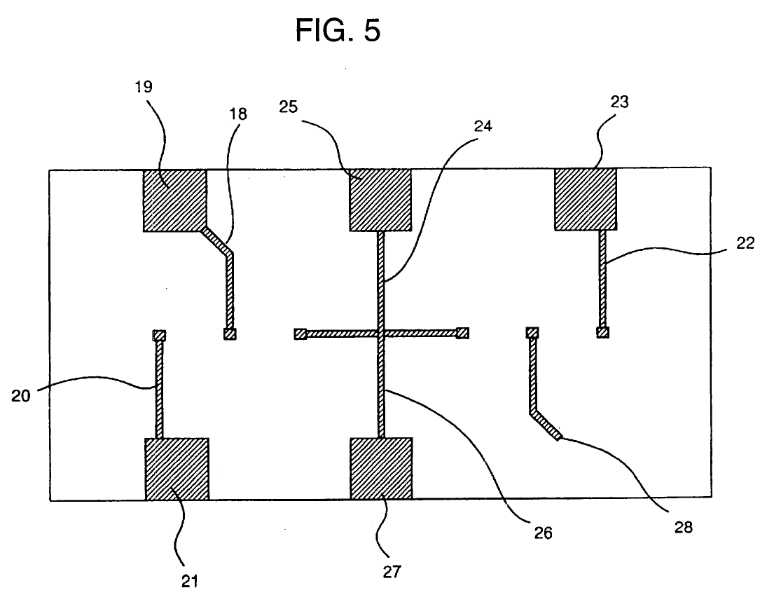

FIG. 1 is a plan view showing the high frequency electronic circuit component which is one example of the present invention. Furthermore, FIG. 2 is a sectional schematic view obtained by cutting FIG. 1 at the A-A′ line thereof. Moreover, each of FIG. 3 to FIG. 5 is a plan schematic view obtained by disintegrating FIG. 1 of the present example into each layer. In the drawings, 1 is the first transmission line, 2 is the second transmission line, and 3 is the third transmission line. Furthermore, 4 is a glass substrate (Nippon Electric Glass Co., Ltd., BLC), and the thickness thereof is 0.5 mm. The numerals 5 and 6 mean an organic insulation material, and a light-sensitive polyimide (Hitachi Chemical Co., Ltd., HD-6000) is used as the material. The numeral 7 is a signal input terminal, and 8 and 9 are output terminals. The numerals 10 and 11 are terminals to be connected to the ground. In fact, these terminals are electrically connected to the terminals for exterior connection shown in FIG. 5 by wiring or the like through the continuity veers provided in an organic insulation layer shown in FIG. 4. The numerals 12 to 17 in FIG. 4 are continuity veers. The terminal 7 in FIG. 3 is connected to external terminal 19 through continuity veer 12 and wiring 18. The terminal 8 in FIG. 3 is connected to external terminal 21 through continuity veer 13 and wiring 20. The terminal 9 in FIG. 3 is connected to external terminal 23 through continuity veer 14 and wiring 22. The terminal 10 in FIG. 3 is connected to external terminal 25 through continuity veer 15 and wiring 24. The terminal 11 in FIG. 3 is connected to external terminal 27 through continuity veer 16 and wiring 26. The terminal 11′ in FIG. 3 is made open through continuity veer 17 and wiring 28.

Next, with regard to the above high frequency electronic circuit component of Example 1, the preparation process thereof is described.

On a glass substrate of 0.5 mm in thickness Cr film of 50 nm was formed by sputtering method and furthermore Cu film of 500 nm was formed, and the resultant two-layer film was used as a fundamental film for copper plating power dispatching. A negative type liquid resist, PMER-N-CA 1000 (manufactured by TOKYO OHKA CO., LTD.) was spin coated on this Cu film and pre-baked with a hot plate, and then a resist mask was formed by way of exposure and development steps. Into the resultant resist openings electric copper plating of 10 μm was formed at an electric current density of 1 A/dm. Thereafter the resist mask was removed, and the copper fundamental film was removed with a copper etching solution, Cobra Etch (manufactured by Ebara Densan K.K.). Moreover, the Cr fundamental film was removed by use of a permanganic acid type Cr etching solution to form the transmission lines shown in FIG. 3.

Next, a light-sensitive polyimide, HD 6000 (manufactured by Hitachi Chemical Co., Ltd.) was coated thereon by spin coating and pre-baked with a hot plate, and then the veers shown in FIG. 4 were formed by way of exposure and development steps. This polyimide was cured at 250° C. for 2 hours in nitrogen atmosphere to form an organic insulation material of 10 μm.

Next, Cr film of 50 nm was formed by sputtering method and furthermore Cu film of 500 nm was formed, and the resultant two-layer film was used as a fundamental film. A negative type liquid resist, PMER-N-CA 1000 (manufactured by TOKYO OHKA CO., LTD.) was spin coated on this Cu film and pre-baked with a hot plate, and then a resist mask was formed by way of exposure and development steps. Into the resultant resist openings electric copper plating of 10 μm was formed at an electric current density of 1 A/dm. Thereafter the resist mask was removed, and the copper fundamental film was removed with a copper etching solution, Cobra Etch (manufactured by Ebara Densan K.K.). Moreover, the Cr fundamental film was removed by use of a permanganic acid type Cr etching solution to form the wiring and external connection terminals shown in FIG. 5. Then, Cu was formed into the veers provided in the organic insulation material as shown in FIG. 2 to electrically connect the terminals of transmission lines on the lower layer shown in FIG. 3 to the terminals shown in FIG. 5.

A light-sensitive polyimide, HD 6000 (manufactured by HDMS) was spin coated on a face wherein the wiring and external connection terminals were formed, and was pre-baked, and then openings for forming solder balls were formed on the external connection terminals by way of exposure and development, and curing was conducted at 250° C. for 1 hour to form another organic insulation material.

Electroless gold plating treatment was conducted on the surfaces of the above external connection terminals, and then solder flux was coated at the predetermined portions through a metal mask, and then lead-free solder balls of 200 μm in diameter were arranged and external electrodes were formed by reflow treatment.

Lastly the resultant product was divided into individual pieces by use of a dicing apparatus to produce high frequency electronic circuit components.

Thus, transmission lines have been formed in two layers heretofore but can be formed in single layer by the present invention, and a high frequency electronic circuit component can be produced fast at a low cost.

Furthermore, it is possible to prevent efficiency reduction of each element by using, as a substrate, a glass of high insulation performance.

Moreover, it goes without saying that use of BCB resin as an organic insulator reduces conductor loss and dielectric loss of a circuit and can provide an electronic circuit component of small passage loss of signal.

Furthermore, it is needless to say that conductor loss and dielectric loss are reduced and loss of signal passing through a high frequency electronic circuit can be reduced at a low cost by using, as an organic insulator, a low dielectric loss tangent resin composition containing a cross-linking component having plural styrene groups represented by the following general formula (1) and furthermore containing a high polymer having a weight average molecular weight of 5000 or higher:

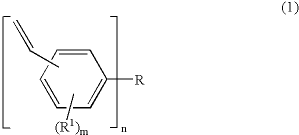

, wherein R means a hydrocarbon skeleton which may have a substituent, R¹ means either one of hydrogen, methyl or ethyl, m means an integer of from 1 to 4, and n means an integer of 2 or more.

In addition, FIG. 1 to FIG. 5 show one example of the present invention, and arrangement of each element should not be limited to this.

### EXAMPLE 2

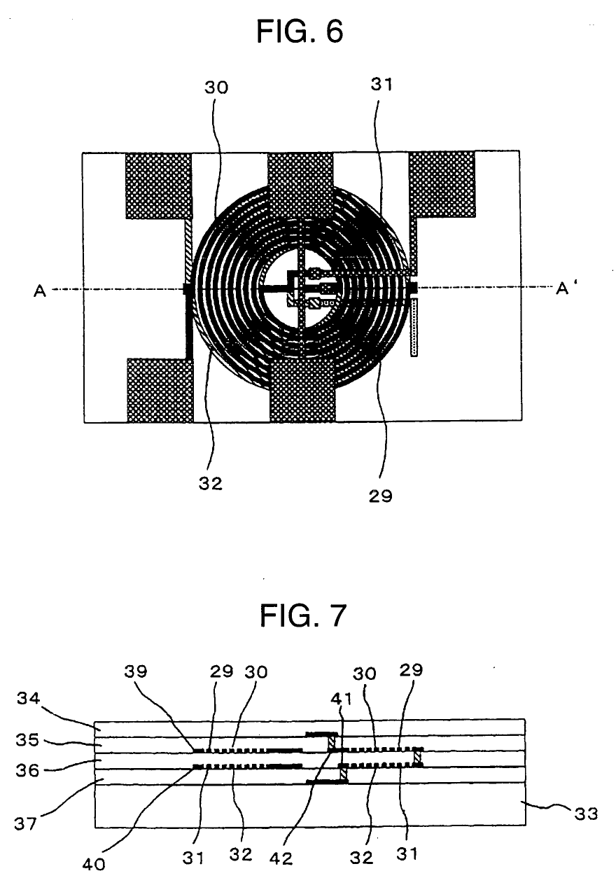

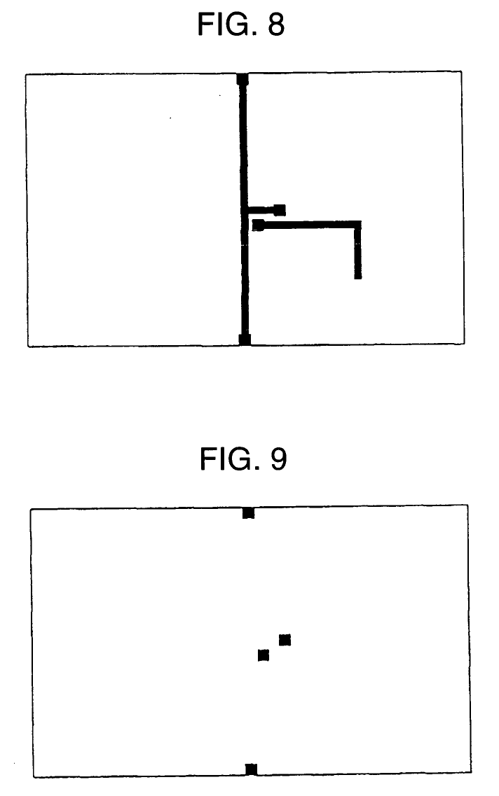

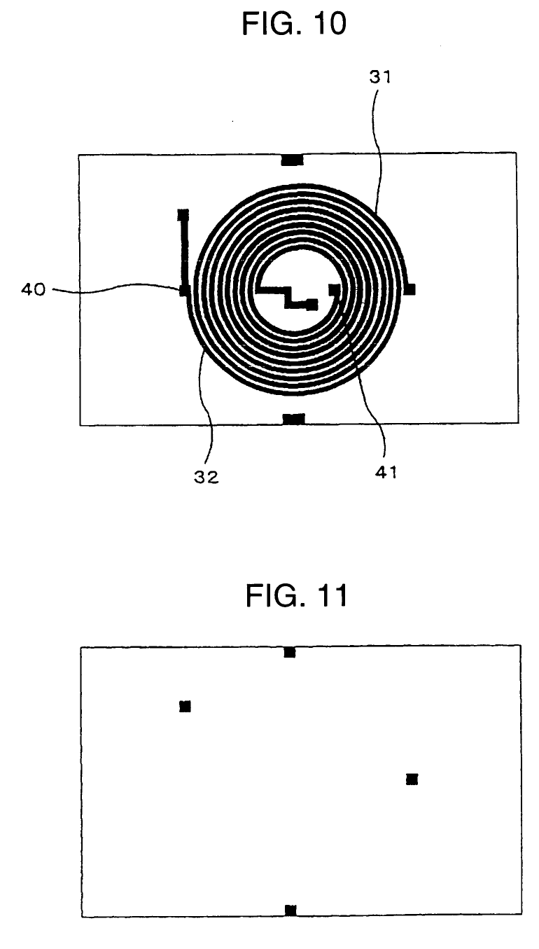

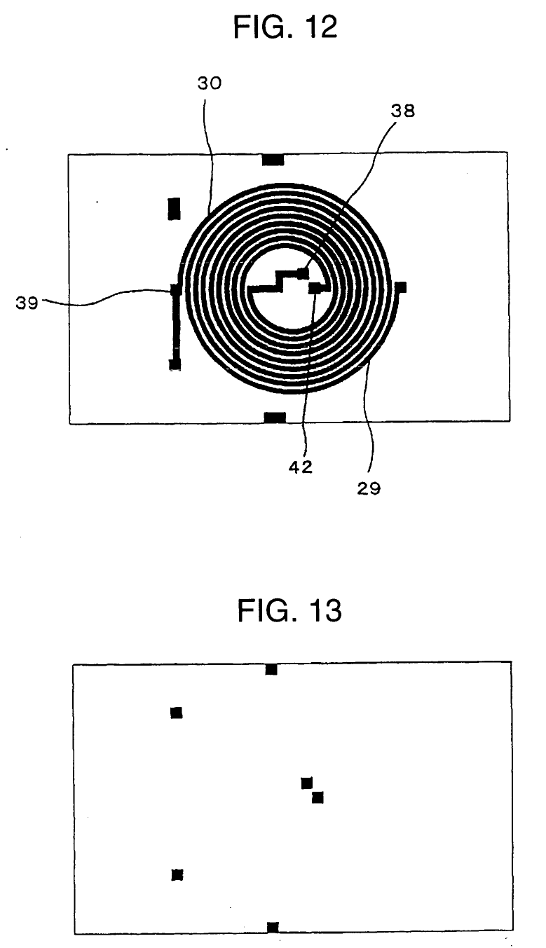

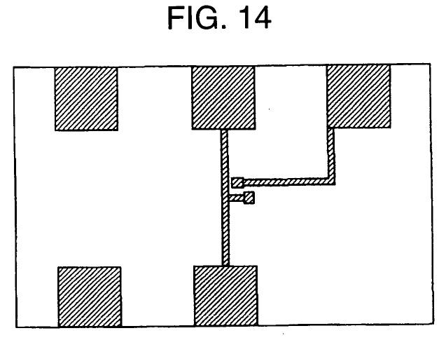

FIG. 6 is a plan view showing the high frequency electronic circuit component which is one example of the present invention. Furthermore, FIG. 7 a sectional schematic view obtained by cutting FIG. 1 at the A-A′ line thereof. Moreover, each of FIG. 8 to FIG. 14 is a plan schematic view obtained by disintegrating FIG. 6 of the present example into each layer. In the drawings, 29 is the first transmission line, 30 is the second transmission line, 31 is the third transmission line, and 32 is the fourth transmission line. Furthermore, 33 is a glass substrate (Nippon Electric Glass Co., Ltd., BLC), and the thickness thereof is 0.5 mm. The numerals 34 to 37 mean an organic insulation material, and a light-sensitive polyimide (Hitachi Chemical Co., Ltd., HD-6000) is used as the material. The numeral 38 is a signal input terminal, and 39 and 40 are output terminals. The numerals 41 and 42 are terminals to be connected to the ground. In fact, these terminals are electrically connected to the wiring, transmission lines, and terminals for exterior connection shown in FIG. 8, FIG. 10, FIG. 12 and FIG. 14 through the continuity veers provided in organic insulation layers shown in FIG. 9, FIG. 11 and FIG. 13.

Next, with regard to the above high frequency electronic circuit component of Example 2, the preparation process thereof is described.

On a glass substrate of 0.5 mm in thickness Cr film of 50 nm was formed by sputtering method and furthermore Cu film of 500 nm was formed, and the resultant two-layer film was used as a fundamental film for copper plating power dispatching. A negative type liquid resist, PMER-N-CA 1000 (manufactured by TOKYO OHKA CO., LTD.) was spin coated on this Cu film and pre-baked with a hot plate, and then a resist mask was formed by way of exposure and development steps. Into the resultant resist openings electric copper plating of 10 μm was formed at an electric current density of 1 A/dm. Thereafter the resist mask was removed, and the copper fundamental film was removed with a copper etching solution, Cobra Etch (manufactured by Ebara Densan K.K.). Moreover, the Cr fundamental film was removed by use of a permanganic acid type Cr etching solution to form the wiring shown in FIG. 8.

Next, a light-sensitive polyimide, HD 6000 (manufactured by Hitachi Chemical Co., Ltd.) was coated thereon by spin coating and pre-baked with a hot plate, and then the veers shown in FIG. 9 were formed by way of exposure and development steps. This polyimide was cured at 250° C. for 2 hours in nitrogen atmosphere to form an organic insulation material of 10 μm.

Next, Cr film of 50 nm was formed by sputtering method and furthermore Cu film of 500 nm was formed, and the resultant two-layer film was used as a fundamental film. A negative type liquid resist, PMER-N-CA 1000 (manufactured by TOKYO OHKA CO., LTD.) was spin coated on this Cu film and pre-baked with a hot plate, and then a resist mask was formed by way of exposure and development steps. Into the resultant resist openings electric copper plating of 10 μm was formed at an electric current density of 1 A/dm. Thereafter the resist mask was removed, and the copper fundamental film was removed with a copper etching solution, Cobra Etch (manufactured by Ebara Densan K.K.). Moreover, the Cr fundamental film was removed by use of a permanganic acid type Cr etching solution to form the transmission lines shown in FIG. 10. Then, Cu was formed into the veers provided in the organic insulation material as shown in FIG. 9 to electrically connect the terminals of wiring on the lower layer shown in FIG. 8 to the terminals of transmission lines shown in FIG. 10.

Next, a light-sensitive polyimide, HD 6000 (manufactured by Hitachi Chemical Co., Ltd.) was coated thereon by spin coating and pre-baked with a hot plate, and then the veers shown in FIG. 11 were formed by way of exposure and development steps. This polyimide was cured at 250° C. for 2 hours in nitrogen atmosphere to form another organic insulation material of 10 μm.

Next, Cr film of 50 nm was formed by sputtering method and furthermore Cu film of 500 nm was formed, and the resultant two-layer film was used as a fundamental film. A negative type liquid resist, PMER-N-CA 1000 (manufactured by TOKYO OHKA CO., LTD.) was spin coated on this Cu film and pre-baked with a hot plate, and then a resist mask was formed by way of exposure and development steps. Into the resultant resist openings electric copper plating of 10 μm was formed at an electric current density of 1 A/dm. Thereafter the resist mask was removed, and the copper fundamental film was removed with a copper etching solution, Cobra Etch (manufactured by Ebara Densan K.K.). Moreover, the Cr fundamental film was removed by use of a permanganic acid type Cr etching solution to form the transmission lines shown in FIG. 12. Then, Cu was formed into the veers provided in the organic insulation material as shown in FIG. 11 to electrically connect the terminals of transmission lines on the lower layer shown in FIG. 10 to the terminals of transmission lines shown in FIG. 12.

Next, a light-sensitive polyimide, HD 6000 (manufactured by Hitachi Chemical Co., Ltd.) was coated thereon by spin coating and pre-baked with a hot plate, and then the veers shown in FIG. 13 were formed by way of exposure and development steps. This polyimide was cured at 250° C. for 2 hours in nitrogen atmosphere to form another organic insulation material of 10 μm.

Next, Cr film of 50 nm was formed by sputtering method and furthermore Cu film of 500 nm was formed, and the resultant two-layer film was used as a fundamental film. A negative type liquid resist, PMER-N-CA 1000 (manufactured by TOKYO OHKA CO., LTD.) was spin coated on this Cu film and pre-baked with a hot plate, and then a resist mask was formed by way of exposure and development steps. Into the resultant resist openings electric copper plating of 10 μm was formed at an electric current density of 1 A/dm. Thereafter the resist mask was removed, and the copper fundamental film was removed with a copper etching solution, Cobra Etch (manufactured by Ebara Densan K.K.). Moreover, the Cr fundamental film was removed by use of a permanganic acid type Cr etching solution to form the wiring and external terminals shown in FIG. 14. Then, Cu was formed into the veers provided in the organic insulation material as shown in FIG. 13 to electrically connect the terminals of transmission lines on the lower layer shown in FIG. 12 to the wiring and external terminals shown in FIG. 14.

A light-sensitive polyimide, HD 6000 (manufactured by HDMS) was spin coated on a face wherein the wiring and external connection terminals were formed, and was pre-baked, and then openings for forming solder balls were formed on the external connection terminals by way of exposure and development, and curing was conducted at 250° C. for 1 hour to form another organic insulation material.

Electroless gold plating treatment was conducted on the surfaces of the above external connection terminals, and then solder flux was coated at the predetermined portions through a metal mask, and then lead-free solder balls of 200 μm in diameter were arranged and external electrodes were formed by reflow treatment.

Lastly the resultant product was divided into individual pieces by use of a dicing apparatus to produce high frequency electronic circuit components.

Thus, transmission lines have been formed in two layers heretofore but can be formed in single layer by the present invention, and a high frequency electronic circuit component can be produced fast at a low cost.

Furthermore, it is possible to prevent efficiency reduction of each element by using, as a substrate, a glass of high insulation performance.

Moreover, it goes without saying that use of BCB resin as an organic insulator reduces conductor loss and dielectric loss of a circuit and can provide an electronic circuit component of small passage loss of signal.

Furthermore, it is needless to say that conductor loss and dielectric loss are reduced and loss of signal passing through a high frequency electronic circuit can be reduced at a low cost by using, as an organic insulator, a low dielectric loss tangent resin composition containing a cross-linking component having plural styrene groups represented by the following general formula (1) and furthermore containing a high polymer having a weight average molecular weight of 5000 or higher:

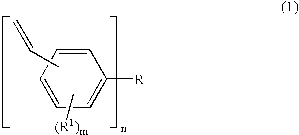

, wherein R means a hydrocarbon skeleton which may have a substituent, R¹ means either one of hydrogen, methyl or ethyl, m means an integer of from 1 to 4, and n means an integer of 2 or more.

In addition, FIG. 6 to FIG. 14 show one example of the present invention, and arrangement of each element should not be limited to this.

It should be further understood by those skilled in the art that although the foregoing description has been made on embodiments of the invention, the invention is not limited thereto and various changes and modifications may be made without departing from the spirit of the invention and the scope of the appended claims.

### EFFECTS OF THE INVENTION

A high frequency electronic circuit component wherein electronic components such as a balun are integrated at a high density, can be obtained in accordance with (1) a high frequency electronic circuit component constituted by three transmission lines formed on at least the same surface, wherein the first and second transmission lines face each other on the same surface and are connected to each other electromagnetically, and the first and third transmission lines face each other on the same surface and are connected to each other electromagnetically.

A high frequency electronic circuit component wherein electronic components such as a balun are integrated at a high density, can be obtained in accordance with (2) a high frequency electronic circuit component constituted by at least four transmission lines, wherein the first and second transmission lines face each other on the same surface and are connected to each other electromagnetically, the third and fourth transmission lines face each other on the same surface and are connected to each other electromagnetically, and the first and third transmission lines are in electric communication with each other.

In addition to the effect of (1) or (2), electronic components such as a balun can be integrated to exhibit higher performances in accordance with (3) the high frequency electronic circuit component of (1) or (2), wherein peripheries of the transmission lines are covered with an organic insulation material, and said transmission lines and said organic insulation material are formed on an insulating substrate.

In addition to the effect of (3), a high frequency electronic circuit component of high performances can be obtained at a lower cost owing to the low cost, high smoothness, high insulation performance and low dielectric loss tangent of a glass substrate in accordance with (4) the high frequency electronic circuit component of (3), wherein the insulating substrate is a glass substrate.

In addition to the effect of (3), a high frequency electronic circuit component can be obtained at a lower cost because production process can be shortened and production cost can be reduced in accordance with (5) the high frequency electronic circuit component of (3), wherein the organic insulation material is a light-sensitive organic insulation material.

In addition to the effect of (3), a high frequency electronic circuit component of higher performances and higher efficiency can be obtained at a low cost owing to the low cost, low dielectric constant and low dielectric loss tangent of a low dielectric loss tangent resin composition in accordance with (6) the high frequency electronic circuit component of (3), wherein the organic insulation material is a low dielectric loss tangent resin composition containing a cross-linking component having plural styrene groups represented by the following general formula (1) and furthermore containing a high polymer having a weight average molecular weight of 5000 or higher:

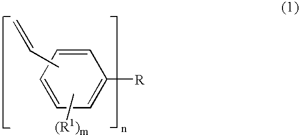

, wherein R means a hydrocarbon skeleton which may have a substituent, R¹ means either one of hydrogen, methyl or ethyl, m means an integer of from 1 to 4, and n means an integer of 2 or more.

In addition to the effect of (3), a high frequency electronic circuit component of high reliability can be obtained owing to the high heat stability of a polyimide in accordance with (7) the high frequency electronic circuit component of (3), wherein the organic insulation material comprises a polyimide resin.

In addition to the effect of (3), a high frequency electronic circuit component of higher performances and higher efficiency can be obtained owing to the low dielectric constant and low dielectric loss tangent of a BCB (benzocyclobutene) resin in accordance with (8) the high frequency electronic circuit component of (3), wherein the organic insulation material comprises BCB (benzocyclobutene) resin.

What is claimed is:

1. A high frequency electronic circuit component constituted by three transmission lines formed on at least the same surface, wherein the first and second transmission lines face each other on the same surface and are connected to each other electromagnetically, and the first and third transmission lines face each other on the same surface and are connected to each other electromagnetically.

2. The high frequency electronic circuit component of claim 1, wherein peripheries of the transmission lines are covered with an organic insulation material, and said transmission lines and said organic insulation material are formed on an insulating substrate.

3. The high frequency electronic circuit component of claim 2, wherein the insulating substrate is a glass substrate.

4. The high frequency electronic circuit component of claim 2, wherein the organic insulation material is a light-sensitive organic insulation material.

5. The high frequency electronic circuit component of claim 2, wherein the organic insulation material is a low dielectric loss tangent resin composition containing a cross-linking component having plural styrene groups represented by the following general formula (1) and furthermore containing a high polymer having a weight average molecular weight of 5000 or higher: 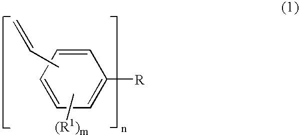
, wherein R means a hydrocarbon skeleton which may have a substituent, R¹ means either one of hydrogen, methyl or ethyl, m means an integer of from 1 to 4, and n means an integer of 2 or more.

6. The high frequency electronic circuit component of claim 2, wherein the organic insulation material comprises a polyimide resin.

7. The high frequency electronic circuit component of claim 2, wherein the organic insulation material comprises BCB (benzocyclobutene) resin.

8. A high frequency electronic circuit component constituted by at least four transmission lines, wherein the first and second transmission lines face each other on the same surface and are connected to each other electromagnetically, the third and fourth transmission lines face each other on the same surface and are connected to each other electromagnetically, and the first and third transmission lines are in electric communication with each other.

9. The high frequency electronic circuit component of claim 8, wherein peripheries of the transmission lines are covered with an organic insulation material, and said transmission lines and said organic insulation material are formed on an insulating substrate.

10. The high frequency electronic circuit component of claim 9, wherein the insulating substrate is a glass substrate.

11. The high frequency electronic circuit component of claim 9, wherein the organic insulation material is a light-sensitive organic insulation material.

12. The high frequency electronic circuit component of claim 9, wherein the organic insulation material is a low dielectric loss tangent resin composition containing a cross-linking component having plural styrene groups represented by the following general formula (1) and furthermore containing a high polymer having a weight average molecular weight of 5000 or higher: 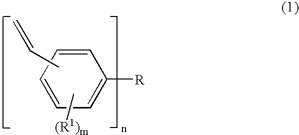
, wherein R means a hydrocarbon skeleton which may have a substituent, R¹ means either one of hydrogen, methyl or ethyl, m means an integer of from 1 to 4, and n means an integer of 2 or more.

13. The high frequency electronic circuit component of claim 9, wherein the organic insulation material comprises a polyimide resin.

14. The high frequency electronic circuit component of claim 9, wherein the organic insulation material comprises BCB (benzocyclobutene) resin.
